(19) United States
(12) Patent Application Publication
(10) Pub. No.: US 2025/0107001 A1
(43) Pub. Date: Mar. 27, 2025

(54) COIL DEVICE AND PRINTED WIRING BOARD

(71) Applicants: SUMITOMO ELECTRIC PRINTED CIRCUITS, INC., Shiga (JP); SUMITOMO ELECTRIC INDUSTRIES, LTD., Osaka (JP)

(72) Inventors: Michi OGATA, Shiga (JP); Takeshi HAMADA, Shiga (JP); Kou NOGUCHI, Shiga (JP); Koji NITTA, Osaka (JP); Shoichiro SAKAI, Osaka (JP); Yosuke FUKAYA, Shiga (JP); Yoshio OKA, Osaka (JP)

(73) Assignees: SUMITOMO ELECTRIC PRINTED CIRCUITS, INC., Shiga (JP); SUMITOMO ELECTRIC INDUSTRIES, LTD., Osaka (JP)

(21) Appl. No.: 18/723,739

(22) PCT Filed: Dec. 23, 2022
(86) PCT No.: PCT/JP2022/047696

§ 371 Date: Jun. 24, 2024

(30) Foreign Application Priority Data
Jan. 5, 2022 (JP) 2022-000509
Feb. 14, 2022 (JP) 2022-020717

(51) Int. Cl. H05K 1/16; H05K 1/11; H05K 3/06; H05K 3/10; H05K 3/18; H05K 3/38

(52) U.S. Cl. CPC H05K 1/165; H05K 1/115; H05K 3/061; H05K 3/108; H05K 3/181; H05K 3/386; H05K 2201/0338

(57) ABSTRACT

A coil device has a first surface and a second surface as end surfaces of the coil device in a thickness direction. The coil device includes at least one printed wiring board, a first protective layer, and an external connection terminal. Each of the at least one printed wiring board has a first base film including a first main surface and a second main surface as a surface opposite to the first main surface, a first coil wire spirally formed on the first main surface, and a second coil wire spirally formed on the second main surface. The first protective layer covers the first main surface of one of the at least one printed wiring board disposed closest to the first surface. The external connection terminal is formed on the first protective layer, and is electrically connected to the first coil wire.

### TECHNICAL FIELD

The present disclosure relates to a coil device and a printed wiring board. The present application claims priority based on Japanese Patent Application No. 2022-509 filed on Jan. 5, 2022 and Japanese Patent Application No. 2022-020717 filed on Feb. 14, 2022. The entire contents described in the Japanese patent applications are incorporated herein by reference.

### BACKGROUND ART

For example, Japanese Patent Laying-Open No. 2016-9854 (PTL 1) describes a printed wiring board. The printed wiring board described in PTL 1 has a base film and a wire. The base film has a first main surface and a second main surface as a surface opposite to the first main surface. The wire has a first wire disposed on the first main surface, and a second wire disposed on the second main surface. The first wire and the second wire are electrically connected with each other via a plating layer disposed on an inner wall surface of a through-hole formed in the base film. The first wire and the second wire are spirally wound to constitute coils.

### CITATION LIST

### Patent Literature

PTL 1: Japanese Patent Laying-Open No. 2016-9854

### SUMMARY OF INVENTION

A coil device of the present disclosure has a first surface and a second surface as end surfaces of the coil device in a thickness direction. The coil device includes at least one printed wiring board, a first protective layer, and an external connection terminal. Each of the at least one printed wiring board has a first base film including a first main surface and a second main surface as a surface opposite to the first main surface, a first coil wire spirally formed on the first main surface, and a second coil wire spirally formed on the second main surface. The first protective layer covers the first main surface of one of the at least one printed wiring board disposed closest to the first surface. The external connection terminal is formed on the first protective layer, and is electrically connected to the first coil wire.

### BRIEF DESCRIPTION OF DRAWINGS

FIG. 1 is a cross sectional view of a coil device 100.

FIG. 2 is a plan view of a printed wiring board 10.

FIG. 3 is a bottom view of printed wiring board 10.

FIG. 4 is a plan view of printed wiring board 10 illustrating the area of a first coil.

FIG. 5 is a cross sectional view of coil device 100 in accordance with a variation.

FIG. 6 is a process chart showing a method for manufacturing coil device 100.

FIG. 7 is a cross sectional view illustrating a seed layer forming step S11.

FIG. 8 is a cross sectional view illustrating a resist forming step S12.

FIG. 9 is a cross sectional view illustrating a first electrolytic plating step S13.

FIG. 10 is a cross sectional view illustrating a resist removing step S14.

FIG. 11 is a cross sectional view illustrating an etching step S15.

FIG. 12 is a cross sectional view illustrating a second electrolytic plating step S16.

FIG. 13 is a cross sectional view illustrating a protective layer forming step S2.

FIG. 14 is a cross sectional view illustrating a through-hole forming step S3.

FIG. 15 is a cross sectional view illustrating an electroless plating step S4.

### DETAILED DESCRIPTION

### [Problem to be Solved by the Present Disclosure]

In the printed wiring board described in PTL 1, it is conceivable to dispose an external connection terminal connected to the wire on the first main surface or the second main surface. In this case, however, the area on the first main surface on which the first wire can be disposed or the area on the second main surface on which the second wire can be disposed is reduced, and the thrust of the coil constituted by the wire is decreased.

The present disclosure has been made in view of the problem of the conventional technique as described above. More specifically, the present disclosure provides a coil device that can improve thrust.

### [Advantageous Effect of the Present Disclosure]

According to the coil device of the present disclosure, thrust can be improved.

### [Description of Embodiments of the Present Disclosure]

First, embodiments of the present disclosure will be described in list form.

(1) A coil device in accordance with an embodiment has a first surface and a second surface as end surfaces of the coil device in a thickness direction. The coil device includes at least one printed wiring board, a first protective layer, and an external connection terminal. Each of the at least one printed wiring board has a first base film including a first main surface and a second main surface as a surface opposite to the first main surface, a first coil wire spirally formed on the first main surface, and a second coil wire spirally formed on the second main surface. The first protective layer covers the first main surface of one of the at least one printed wiring board disposed closest to the first surface. The external connection terminal is formed on the first protective layer, and is electrically connected to the first coil wire.

According to the coil device in (1), thrust can be improved.

(2) The coil device in (1) may further include a conductive layer that electrically connects the external connection terminal and the first coil wire of the one of the at least one printed wiring board disposed closest to the first surface. A through-hole that penetrates through the first protective layer may be formed in the first protective layer. The through-hole may partially expose the first coil wire of the one of the at least one printed wiring board disposed closest to the first surface. The conductive layer may be formed on the first coil wire exposed from the through-hole and on an inner wall surface of the through-hole.

(3) The coil device in (1) or (2) may further include at least one first adhesive layer. The at least one printed wiring board may be a plurality of printed wiring boards. The at least one first adhesive layer may be disposed between two adjacent printed wiring boards of the plurality of printed wiring boards.

(4) In the coil device in (3), a number of the plurality of printed wiring boards may be two or three.

(5) In the coil device in (1) to (4), the first protective layer may have a second adhesive layer that covers the first main surface of the one of the at least one printed wiring board disposed closest to the first surface, and a second base film disposed on the second adhesive layer.

(6) The coil device in (1) to (5) may further include a second protective layer. The second protective layer may cover the second main surface of one of the at least one printed wiring board disposed closest to the second surface.

(7) In the coil device in (6), the second protective layer may have a third adhesive layer that covers the second main surface of the one of the at least one printed wiring board disposed closest to the second surface, and a third base film disposed on the third adhesive layer.

(8) In the coil device in (6) or (7), a thickness of the first protective layer may be more than or equal to 5 μm and less than or equal to 50 μm, and may be more than or equal to 0.8 times and less than or equal to 1.2 times a thickness of the second protective layer.

(9) In the coil device in (1) to (8), at least one of a value obtained by dividing an area of a coil constituted by the first coil wire by an area of the first main surface and a value obtained by dividing an area of a coil constituted by the second coil wire by an area of the second main surface may be more than or equal to 0.40 and less than or equal to 0.90.

(10) In the coil device in (1) to (9), at least one of a value obtained by dividing an area of a coil constituted by the first coil wire by an area of the first main surface and a value obtained by dividing an area of a coil constituted by the second coil wire by an area of the second main surface may be more than or equal to 0.60 and less than or equal to 0.90.

(11) In the coil device in (1) to (10), a width of the first coil wire and a width of the second coil wire may be more than or equal to 20 μm and less than or equal to 40 μm. A thickness of the first coil wire and a thickness of the second coil wire may be more than or equal to 30 μm and less than or equal to 70 μm. A distance between two adjacent portions of the first coil wire and a distance between two adjacent portions of the second coil wire may be more than or equal to 3 μm and less than or equal to 15 μm.

(12) In the coil device in (1) to (11), a value obtained by dividing an area of a coil constituted by the first coil wire by an area of the first main surface may be more than or equal to 0.95 times and less than or equal to 1.05 times a value obtained by dividing an area of a coil constituted by the second coil wire by an area of the second main surface.

(13) A printed wiring board in accordance with an embodiment includes a first

base film having a first main surface and a second main surface as a surface opposite to the first main surface, a first coil wire spirally formed on the first main surface, and a second coil wire spirally formed on the second main surface. At least one of a value obtained by dividing an area of a coil constituted by the first coil wire by an area of the first main surface and a value obtained by dividing an area of a coil constituted by the second coil wire by an area of the second main surface is more than or equal to 0.40 and less than or equal to 0.90.

According to the printed wiring board in (13), thrust can be improved when it is used for a coil device.

(14) In the printed wiring board in (13), the at least one of the value obtained by

dividing the area of the coil constituted by the first coil wire by the area of the first main surface and the value obtained by dividing the area of the coil constituted by the second coil wire by the area of the second main surface may be more than or equal to 0.60 and less than or equal to 0.90.

(15) In the printed wiring board in (13) or (14), the value obtained by dividing the area of the coil constituted by the first coil wire by the area of the first main surface may be more than or equal to 0.95 times and less than or equal to 1.05 times the value obtained by dividing the area of the coil constituted by the second coil wire by the area of the second main surface.

(16) A printed wiring board in accordance with another embodiment includes a first base film having a first main surface and a second main surface as a surface opposite to the first main surface, a first coil wire spirally formed on the first main surface, and a second coil wire spirally formed on the second main surface. A value obtained by dividing a width of the first coil wire by a pitch between two adjacent portions of the first coil wire and a value obtained by dividing a width of the second coil wire by a pitch between two adjacent portions of the second coil wire are more than or equal to 0.72 and less than or equal to 0.93.

According to the printed wiring board in (16), thrust can be improved when it is used for a coil device.

### [Details of Embodiments of the Present Disclosure]

Next, details of the embodiments of the present disclosure will be described with reference to the drawings. In the drawings below, identical or corresponding parts will be designated by the same reference numerals, and overlapping description will not be repeated.

(Configuration of Coil Device in Accordance with Embodiment)

In the following, a configuration of a coil device in accordance with an embodiment will be described. The coil device in accordance with the embodiment is referred to as a coil device 100.

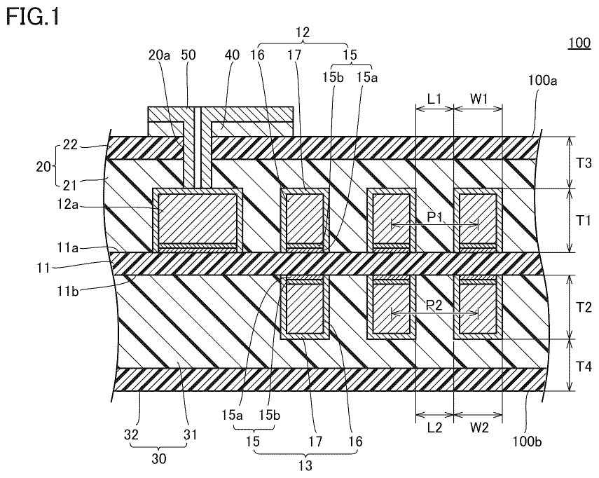

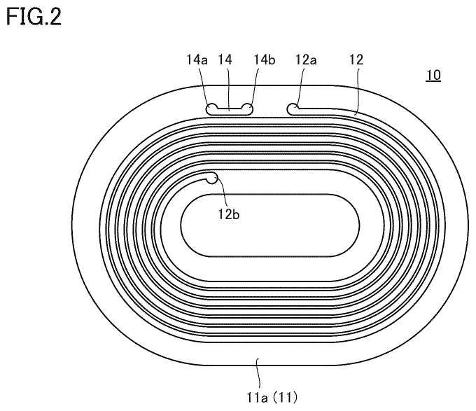

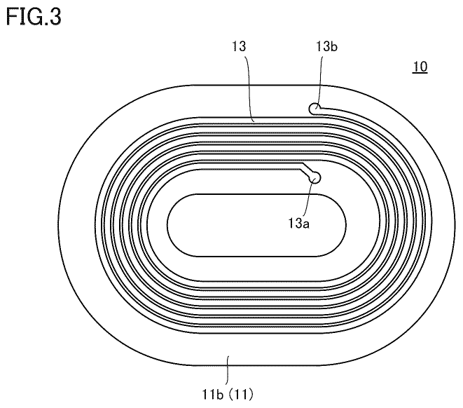

FIG. 1 is a cross sectional view of coil device 100. FIG. 2 is a plan view of a printed wiring board 10. FIG. 3 is a bottom view of printed wiring board 10. FIG. 3 shows printed wiring board 10 seen from a side opposite to that in FIG. 2. As shown in FIGS. 1, 2, and 3, coil device 100 has printed wiring board 10, a first protective layer 20, a second protective layer 30, an external connection terminal 40, and a conductive layer 50. Coil device 100 has a first surface 100a and a second surface 100b. First surface 100a and second surface 100b are end surfaces of coil device 100 in a thickness direction. Second surface 100b is a surface opposite to first surface 100a.

Printed wiring board 10 has a base film 11, a first coil wire 12, a second coil wire 13, and a connection wire 14.

Base film 11 has a first main surface 11a and a second main surface 11b. First main surface 11a and second main surface 11b are end surfaces of base film 11 in the thickness direction. Base film 11 is made of a flexible electrical insulating material. Base film 11 is made of polyimide, polyethylene terephthalate, or fluororesin, for example.

First coil wire 12 is disposed on first main surface 11a. First coil wire 12 is spirally wound in plan view. Second coil wire 13 is disposed on second main surface 11b. Second coil wire 13 is spirally wound in plan view. Connection wire 14 is disposed on first main surface 11a.

One end and the other end of first coil wire 12 serve as a land 12a and a land

12b, respectively. One end of second coil wire 13 serve as a land 13a and a land 13b, respectively. One end and the other end of connection wire 14 serve as a land 14a and a land 14b, respectively. Land 12b and land 13a overlap with each other in plan view. Land 13b and land 14a overlap with each other in plan view.

In base film 11, a through-hole 11c (not shown) and a through-hole 11d (not shown) that penetrate through base film 11 along the thickness direction are formed. Through-hole 11c overlaps with land 12b and land 13a in plan view. Through-hole 11d overlaps with land 13b and land 14a in plan view. First coil wire 12 and second coil wire 13 are electrically connected with each other by a conductive layer 11e (not shown) formed on an inner wall surface of through-hole 11c. Second coil wire 13 and connection wire 14 are electrically connected with each other by a conductive layer 11f (not shown) formed on an inner wall surface of through-hole 11d.

Each of first coil wire 12 and second coil wire 13 has a seed layer 15, a first electrolytic plating layer 16, and a second electrolytic plating layer 17.

Seed layer 15 is disposed on each main surface (first main surface 11a, second main surface 11b) of base film 11. Seed layer 15 has a first layer 15a and a second layer 15b. First layer 15a is disposed on each main surface (first main surface 11a, second main surface 11b) of base film 11. Second layer 15b is disposed on first layer 15a.

First layer 15a is, for example, a sputtered layer (a layer formed by sputtering) made of a nickel-chromium alloy. Second layer 15b is, for example, an electroless plating layer (a layer formed by electroless plating) made of copper.

First electrolytic plating layer 16 is disposed on seed layer 15. First electrolytic plating layer 16 is an electrolytic plating layer made of copper. Second electrolytic plating layer 17 covers seed layer 15 and first electrolytic plating layer 16. More specifically, second electrolytic plating layer 17 is disposed on side surfaces of seed layer 15, and on side surfaces and an upper surface of first electrolytic plating layer 16.

A coil constituted by first coil wire 12 is referred to as a first coil. A coil constituted by second coil wire 13 is referred to as a second coil. Preferably, at least one of an area ratio of the first coil and an area ratio of the second coil is more than or equal to 0.40 and less than or equal to 0.90. More preferably, at least one of the area ratio of the first coil and the area ratio of the second coil is more than or equal to 0.60 and less than or equal to 0.90. Preferably, the area ratio of the first coil is more than or equal to 0.95 times and less than or equal to 1.05 times the area ratio of the second coil.

The area ratio of the first coil is a value obtained by dividing an area of the first coil by an area of first main surface 11a, and the area ratio of the second coil is a value obtained by dividing an area of the second coil by an area of second main surface 11b. The area of the first coil is the sum of an area of first coil wire 12 and an area of first main surface 11a located between two adjacent portions of first coil wire 12. The area of the second coil is the sum of an area of second coil wire 13 and an area of second main surface 11b located between two adjacent portions of second coil wire 13.

The area of first coil wire 12 is the area of first coil wire 12 in plan view seen from a first main surface 11a side. That is, the area of first coil wire 12 does not include an area of side surfaces of first coil wire 12. The area of second coil wire 13 is the area of second coil wire 13 in plan view seen from a second main surface 11b side. That is, the area of second coil wire 13 does not include an area of side surfaces of second coil wire 13.

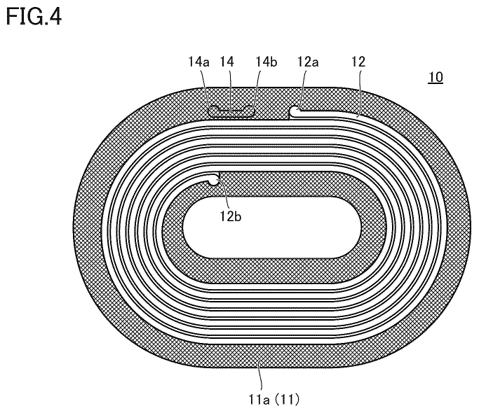

FIG. 4 is a plan view of printed wiring board 10 illustrating the area of the first coil. As shown in FIG. 4, an area of first main surface 11a located other than between the two adjacent portions of first coil wire 12 (a cross-hatched portion in FIG. 4) is not included in the area of the first coil. Although not shown, second main surface 11b located other than between the two adjacent portions of second coil wire 13 is also not included in the area of the second coil.

A width of first coil wire 12 is referred to as a width W1, and a width of second coil wire 13 is referred to as a width W2. Preferably, width W1 and width W2 are more than or equal to 20 μm and less than or equal to 40 μm. A thickness of first coil wire 12 is referred to as a thickness T1. A thickness of second coil wire 13 is referred to as a thickness T2. Preferably, thickness T1 and thickness T2 are more than or equal to 30 μm and less than or equal to 70 μm. A distance between the two adjacent portions of first coil wire 12 is referred to as a distance L1. A distance between the two adjacent portions of second coil wire 13 is referred to as a distance L2. Preferably, distance L1 and distance L2 are more than or equal to 3 μm and less than or equal to 15 μm.

A pitch between the two adjacent portions of first coil wire 12 is referred to as a pitch P1. A pitch between the two adjacent portions of second coil wire 13 is referred to as a pitch P2. Preferably, a value obtained by dividing width W1 by pitch P1 and a value obtained by dividing width W2 by pitch P2 are more than or equal to 0.72 and less than or equal to 0.93.

First protective layer 20 covers first main surface 11a. First protective layer 20 has an adhesive layer 21 and a base film 22. Adhesive layer 21 covers first main surface 11a. Base film 22 is disposed on adhesive layer 21. Adhesive layer 21 is made of an adhesive, for example. Base film 22 is made of polyimide, polyethylene terephthalate, or fluororesin, for example.

In first protective layer 20, a through-hole 20a is formed. Through-hole 20a penetrates through first protective layer 20 along the thickness direction to partially expose first coil wire 12. From through-hole 20a, a land 12a is exposed, for example. A thickness of first protective layer 20 is referred to as a thickness T3. Thickness T3 is a distance between an upper surface of first coil wire 12 and a surface of first protective layer 20. Preferably, thickness T3 is more than or equal to 5 μm and less than or equal to 50 μm.

Second protective layer 30 covers second main surface 11b. Second protective layer 30 has an adhesive layer 31 and a base film 32. Adhesive layer 31 covers second main surface 11b. Base film 32 is disposed on adhesive layer 31. Adhesive layer 31 is made of an adhesive, for example. Base film 32 is made of polyimide, polyethylene terephthalate, or fluororesin, for example.

A thickness of second protective layer 30 is referred to as a thickness T4. Thickness T4 is a distance between an upper surface of second coil wire 13 and a surface of second protective layer 30. Preferably, thickness T4 is more than or equal to 5 μm and less than or equal to 50 μm. Preferably, thickness T3 is more than or equal to 0.8 times and less than or equal to 1.2 times thickness T4.

External connection terminal 40 is disposed on first protective layer 20 (base film 22). External connection terminal 40 is made of copper, for example. Conductive layer 50 is an electroless plating layer made of copper, for example. Conductive layer 50 is disposed on a portion of first coil wire 12 exposed from through-hole 20a (for example, land 12a) and on an inner wall surface of through-hole 20a. Further, conductive layer 50 is also disposed on external connection terminal 40. Accordingly, conductive layer 50 electrically connects external connection terminal 40 and first coil wire 12.

Although not shown, a through-hole 20b different from through-hole 20a is formed in first protective layer 20 to expose land 14b, and an external connection terminal 41 different from external connection terminal 40 is disposed on first protective layer 20. Further, a conductive layer 51 (not shown) different from conductive layer 50 is disposed on an inner wall surface of through-hole 20b, on land 14b, and on external connection terminal 41, and thereby external connection terminal 41 is electrically connected to connection wire 14.

Since connection wire 14 is electrically connected to second coil wire 13 and second coil wire 13 is electrically connected to first coil wire 12, a current flows through first coil wire 12 and second coil wire 13 by applying a voltage between external connection terminal 40 and external connection terminal 41, and the first coil and the second coil generate a magnetic field.

### <Variation>

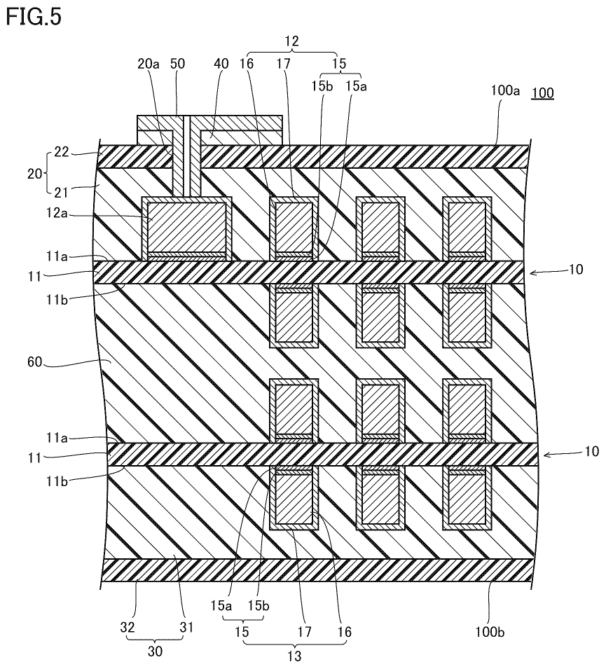

FIG. 5 is a cross sectional view of coil device 100 in accordance with a variation. As shown in FIG. 5, coil device 100 may have a plurality of printed wiring boards 10. Preferably, the number of printed wiring boards 10 is two or three. In this case, two printed wiring boards 10 adjacent in the thickness direction of coil device 100 adhere to each other with an adhesive layer 60. Further, in this case, first protective layer 20 covers first main surface 11a of printed wiring board 10 located closest to first surface 100a, and second protective layer 30 covers second main surface 11b of printed wiring board 10 located closest to second surface 100b.

(Method for Manufacturing Coil Device in Accordance with Embodiment)

In the following, a method for manufacturing coil device 100 will be described.

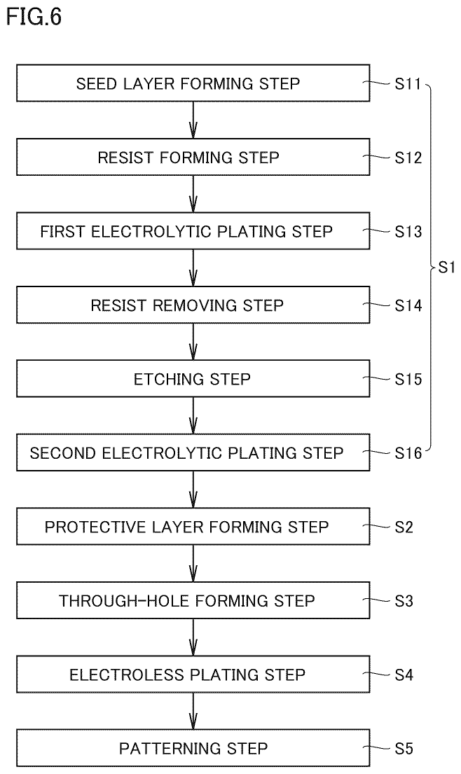

FIG. 6 is a process chart showing a method for manufacturing coil device 100. As shown in FIG. 6, the method for manufacturing coil device 100 has a printed wiring board forming step S1, a protective layer forming step S2, a through-hole forming step S3, an electroless plating step S4, and a patterning step S5. Printed wiring board forming step SI has a seed layer forming step S11, a resist forming step S12, a first electrolytic plating step S13, a resist removing step S14, an etching step S15, and a second electrolytic plating step S16.

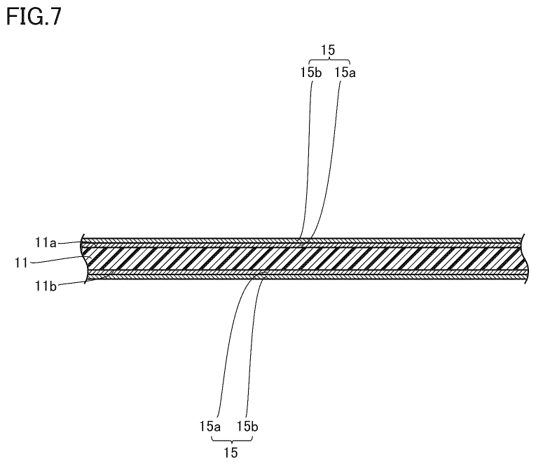

FIG. 7 is a cross sectional view illustrating seed layer forming step S11. In seed layer forming step S11, seed layer 15 (first layer 15a, second layer 15b) is formed. In seed layer forming step S11, firstly, first layer 15a is formed on each of first main surface 11a and second main surface 11b. First layer 15a is formed by sputtering, for example. Secondly, although not shown, through-hole 11c and through-hole 11d are formed. Through-hole 11c and through-hole 11d are formed by projecting laser light, for example.

Thirdly, second layer 15b is formed on first layer 15a. Although not shown, second layer 15b is also formed on the inner wall surfaces of through-hole 11c and through-hole 11d. Formation of second layer 15b is formed by electroless plating, for example.

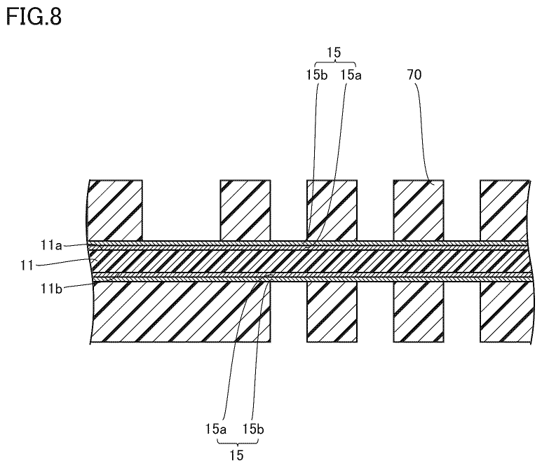

FIG. 8 is a cross sectional view illustrating resist forming step S12. As shown in FIG. 8, in resist forming step S12, a resist 70 is formed. Resist 70 is formed, for example, by attaching a dry film resist on seed layer 15, and exposing the attached dry film resist to light and developing it for patterning.

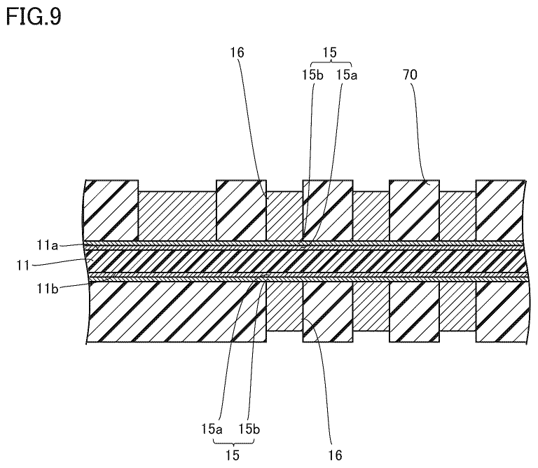

FIG. 9 is a cross sectional view illustrating first electrolytic plating step S13. As shown in FIG. 9, in first electrolytic plating step S13, first electrolytic plating layer 16 is formed on seed layer 15 exposed from resist 70. Although not shown, first electrolytic plating layer 16 is also formed on second layer 15b located on the inner wall surfaces of through-hole 11c and through-hole 11d. First electrolytic plating layer 16 is formed by energizing seed layer 15 in a plating solution containing a material constituting first electrolytic plating layer 16.

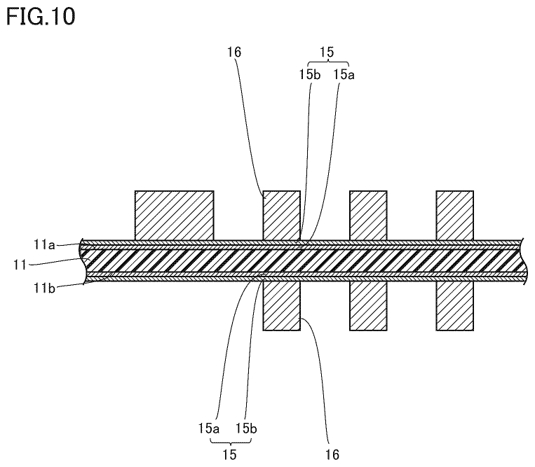

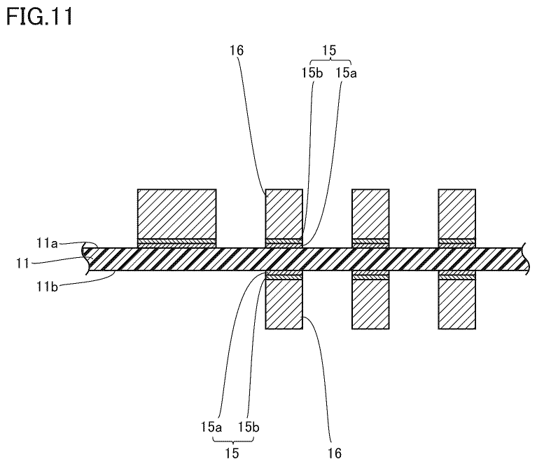

FIG. 10 is a cross sectional view illustrating resist removing step S14. As shown in FIG. 10, in resist removing step S14, resist 70 is peeled off and thereby removed. FIG. 11 is a cross sectional view illustrating etching step S15. As shown in FIG. 11, in etching step S15, seed layer 15 exposed from between two adjacent portions of first electrolytic plating layer 16 is removed by etching.

In etching step S15, firstly, etching on second layer 15b is performed. The etching on second layer 15b is performed by supplying an etching solution to between the two adjacent portions of first electrolytic plating layer 16. The etching solution is selected to control the rate of etching by a reaction between reacting species in the etching solution and an etching target, instead of diffusion of reacting species in the etching solution to the vicinity of an etching target.

More specifically, as the etching solution, an etching solution having a dissolution reaction rate of less than or equal to 1.0 μm/minute with respect to a material constituting second layer 15b (that is, copper) is used. A specific example of the etching solution described above includes a sulfuric acid hydrogen peroxide solution or a sodium peroxodisulfate solution. It should be noted that the dissolution reaction rate of the etching solution described above is measured based on the weight of copper decreased after the etching, and an etching time.

In etching step S15, secondly, etching on first layer 15a is performed. The etching solution is switched when the etching of first layer 15a is performed. As an etching solution after the switching, an etching solution having a high selectivity with respect to a material constituting first layer 15a (that is, a nickel-chromium alloy) is used. Accordingly, after the etching solution is switched, etching on first electrolytic plating layer 16 is less likely to proceed.

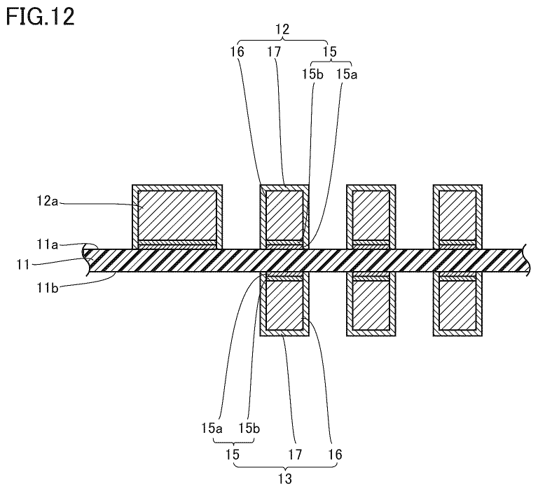

FIG. 12 is a cross sectional view illustrating second electrolytic plating step S16. As shown in FIG. 12, in second electrolytic plating step S16, second electrolytic plating layer 17 is formed to cover seed layer 15 and first electrolytic plating layer 16. It should be noted that, although not shown, second electrolytic plating layer 17 is also formed on first electrolytic plating layer 16 located on the inner wall surfaces of through-hole 11c and through-hole 11d with second layer 15b being interposed therebetween. From another viewpoint, conductive layer 11e and conductive layer 1 1f are constituted by second layer 15b, first electrolytic plating layer 16, and second electrolytic plating layer 17.

Second electrolytic plating layer 17 is formed by energizing seed layer 15 and first electrolytic plating layer 16 in a plating solution containing a material constituting second electrolytic plating layer 17. Thus, printed wiring board 10 is formed using a semi-additive process.

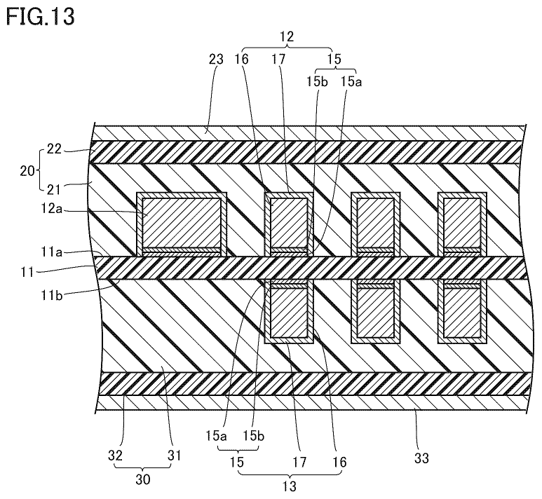

FIG. 13 is a cross sectional view illustrating protective layer forming step S2. As shown in FIG. 13, in protective layer forming step S2, first protective layer 20 is formed on first main surface 11a, and second protective layer 30 is formed on second main surface 11b. In protective layer forming step S2, firstly, base film 22 to which adhesive layer 21 is applied is disposed on first main surface 11a to cover first coil wire 12, and base film 32 to which adhesive layer 31 is applied is disposed on second main surface 11b to cover second coil wire 13. At this stage, adhesive layer 21 and adhesive layer 31 are not cured. Secondly, base film 22 and base film 32 are pressurized toward base film 11, with being heated. Thereby, adhesive layer 21 and adhesive layer 31 are cured, and base film 22 and base film 32 are attached.

It should be noted that, at the time when protective layer forming step S2 is performed, a copper layer 23 is disposed on base film 22, and a copper layer 33 is disposed on base film 32.

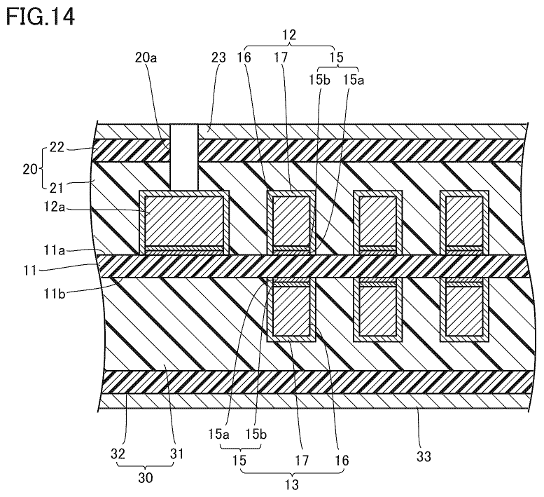

FIG. 14 is a cross sectional view illustrating through-hole forming step S3. As shown in FIG. 14, in through-hole forming step S3, through-hole 20a is formed in first protective layer 20. Through-hole 20a is formed by projecting laser light, for example. Although not shown, through-hole 20b is also formed similarly.

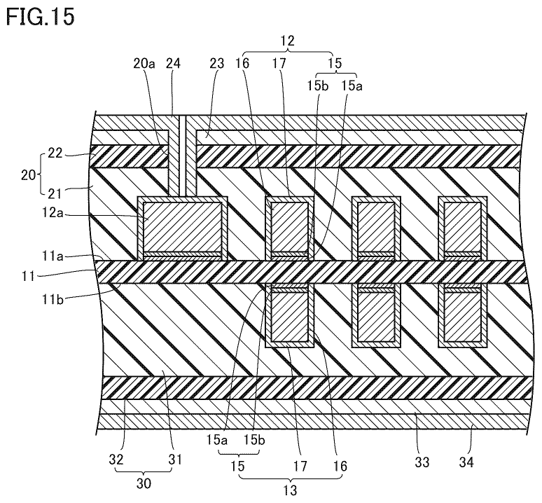

FIG. 15 is a cross sectional view illustrating electroless plating step S4. As shown in FIG. 15, in electroless plating step S4, an electroless plating layer 24 is formed on copper layer 23, and an electroless plating layer 34 is formed on copper layer 33. Electroless plating layer 24 and electroless plating layer 34 are performed by immersing printed wiring board 10 having first protective layer 20 and second protective layer 30 formed thereon in a plating solution containing a material constituting electroless plating layer 24 and electroless plating layer 34.

In patterning step S5, copper layer 23 and electroless plating layer 24 are patterned to form external connection terminal 40 and conductive layer 50. Although not shown, external connection terminal 41 and conductive layer 51 are also formed as copper layer 23 and electroless plating layer 24 are patterned.

Patterning of copper layer 23 and electroless plating layer 24 is performed by attaching a dry film resist, for example, on electroless plating layer 24, exposing the attached dry film resist to light and developing it to form a resist, and etching copper layer 23 and electroless plating layer 24 using the resist as a mask. It should be noted that, since the resist is not formed on electroless plating layer 34, copper layer 33 and electroless plating layer 34 are all removed by the etching described above. Thus, coil device 100 having a structure shown in FIG. 1 is formed.

(Effect of Coil Device in Accordance with Embodiment)

In the following, the effect of coil device 100 will be described.

Concerning the disposition of external connection terminal 40 and external connection terminal 41, it is conceivable to dispose external connection terminal 40 and external connection terminal 41 on first main surface 11a. In this case, however, as external connection terminal 40 and external connection terminal 41 are disposed on first main surface 11a, the area of first main surface 11a on which first coil wire 12 can be disposed is reduced. As a result, the area ratio of the first coil is decreased when compared with the area ratio of the second coil.

In contrast, in coil device 100, external connection terminal 40 and external connection terminal 41 are disposed on first protective layer 20, and thus the area of first main surface 11a on which first coil wire 12 can be disposed is not reduced. Accordingly, in coil device 100, the area ratio of the first coil can be set to be substantially the same as the area ratio of the second coil, and the thrust of coil device 100 can be improved.

Conventionally, an etching solution having a high dissolution reaction rate with respect to a material constituting a seed layer (that is, an etching solution in which diffusion of reacting species in the etching solution to the vicinity of an etching target controls the rate of etching) has been used. When the distance between two adjacent portions of a coil wire is shortened, the etching solution is less likely to be supplied to between the two adjacent portions of the coil wire. Further, also when the thickness of the coil wire is increased, the etching solution is less likely to be supplied to between the two adjacent portions of the coil wire.

As a result, when the etching solution as described above is used, etching on the seed layer varies widely, and the amount of etching increases in order to remove the seed layer reliably. Due to the reason as described above, it has been conventionally impossible to shorten the distance between the two adjacent portions of the coil wire, and to increase the thickness of the coil wire.

In printed wiring board 10, in etching step S15, the etching solution having a low dissolution reaction rate with respect to the material constituting second layer 15b is used. As a result, the rate of etching in etching step S15 is controlled by a reaction between reacting species in the etching solution and an etching target, and the etching of second layer 15b is less likely to vary even if the etching solution is less likely to be supplied to between the two adjacent portions of first electrolytic plating layer 16.

Accordingly, according to printed wiring board 10, the distance between the two adjacent portions of first coil wire 12 (second coil wire 13) can be shortened, and the thickness of first coil wire 12 (second coil wire 13) can be increased. As a result, the area ratio of the first coil and the area ratio of the second coil can be increased, and the thrust of coil device 100 can be improved.

Further, by shortening the distance between the two adjacent portions of first coil wire 12 (second coil wire 13), the width of first coil wire 12 (second coil wire 13) can be increased. Accordingly, according to printed wiring board 10, the thickness and the width of first coil wire 12 (second coil wire 13) can be increased, and the electric resistance value of first coil wire 12 (second coil wire 13) decreases. As a result, an increase in electric resistance value associated with an increase in the area ratio of the first coil and the area ratio of the second coil can be suppressed.

It should be understood that the embodiments disclosed herein are illustrative and non-restrictive in every respect. The scope of the present invention is defined by the scope of the claims, rather than the embodiments described above, and is intended to include any modifications within the scope and meaning equivalent to the scope of the claims.

### REFERENCE SIGNS LIST

100: coil device;

10: printed wiring board;

11: base film;

11a: first main surface;

11b: second main surface;

11c: through-hole;

11d: through-hole;

11e, 11f: conductive layer;

12: first coil wire;

12a, 12b: land;

13: second coil wire;

13a, 13b: land;

14: connection wire;

14a: land;

14b: land;

15: seed layer;

15a: first layer;

15b: second layer;

16: first electrolytic plating layer;

17: second electrolytic plating layer;

20: first protective layer;

20a, 20b: through-hole;

21: adhesive layer;

22: base film;

23: copper layer;

24: electroless plating layer;

30: second protective layer;

31: adhesive layer;

32: base film;

33: copper layer;

34: electroless plating layer;

40, 41: external connection terminal;

50, 51: conductive layer;

60: adhesive layer;

70: resist;

100a: first surface;

100b: second surface;

L1, L2: distance;

P1, P2: pitch;

S1: printed wiring board forming step;

S2: protective layer forming step;

S3: through-hole forming step;

S4: electroless plating step;

S5: patterning step;

S11: seed layer forming step;

S12: resist forming step;

S13: first electrolytic plating step;

S14: resist removing step;

S15: etching step;

S16: second electrolytic plating step;

T1, T2, T3, T4: thickness;

W1, W2: width.

1. A coil device comprising:
at least one printed wiring board;
a first protective layer; and
an external connection terminal, wherein
the coil device has a first surface and a second surface as end surfaces of the coil device in a thickness direction,
each of the at least one printed wiring board has a first base film including a first main surface and a second main surface as a surface opposite to the first main surface, a first coil wire spirally formed on the first main surface, and a second coil wire spirally formed on the second main surface,
the first protective layer covers the first main surface of one of the at least one printed wiring board disposed closest to the first surface, and
the external connection terminal is formed on the first protective layer, and is electrically connected to the first coil wire.

2. The coil device according to claim 1, further comprising a conductive layer that electrically connects the external connection terminal and the first coil wire of the one of the at least one printed wiring board disposed closest to the first surface, wherein
a through-hole that penetrates through the first protective layer is formed in the first protective layer,
the through-hole partially exposes the first coil wire of the one of the at least one printed wiring board disposed closest to the first surface, and
the conductive layer is formed on the first coil wire exposed from the through-hole and on an inner wall surface of the through-hole.

3. The coil device according to claim 1, further comprising at least one first adhesive layer, wherein
the at least one printed wiring board is a plurality of printed wiring boards, and
the at least one first adhesive layer is disposed between two adjacent printed wiring boards of the plurality of printed wiring boards.

4. The coil device according to claim 3, wherein a number of the plurality of printed wiring boards is two or three.

5. The coil device according claim 1, wherein the first protective layer has a second adhesive layer that covers the first main surface of the one of the at least one printed wiring board disposed closest to the first surface, and a second base film disposed on the second adhesive layer.

6. The coil device according to claim 1, further comprising a second protective layer, wherein the second protective layer covers the second main surface of one of the at least one printed wiring board disposed closest to the second surface.

7. The coil device according to claim 6, wherein the second protective layer has a third adhesive layer that covers the second main surface of the one of the at least one printed wiring board disposed closest to the second surface, and a third base film disposed on the third adhesive layer.

8. The coil device according to claim 6, wherein a thickness of the first protective layer is more than or equal to 5 μm and less than or equal to 50 μm, and is more than or equal to 0.8 times and less than or equal to 1.2 times a thickness of the second protective layer.

9. The coil device according to claim 1, wherein at least one of a value obtained by dividing an area of a coil constituted by the first coil wire by an area of the first main surface and a value obtained by dividing an area of a coil constituted by the second coil wire by an area of the second main surface is more than or equal to 0.40 and less than or equal to 0.90.

10. The coil device according to claim 1, wherein at least one of a value obtained by dividing an area of a coil constituted by the first coil wire by an area of the first main surface and a value obtained by dividing an area of a coil constituted by the second coil wire by an area of the second main surface is more than or equal to 0.60 and less than or equal to 0.90.

11. The coil device according to claim 1, wherein
a width of the first coil wire and a width of the second coil wire are more than or equal to 20 μm and less than or equal to 40 μm,
a thickness of the first coil wire and a thickness of the second coil wire are more than or equal to 30 μm and less than or equal to 70 μm, and
a distance between two adjacent portions of the first coil wire and a distance between two adjacent portions of the second coil wire are more than or equal to 3 μm and less than or equal to 15 μm.

12. The coil device according to claim 1, wherein a value obtained by dividing an area of a coil constituted by the first coil wire by an area of the first main surface is more than or equal to 0.95 times and less than or equal to 1.05 times a value obtained by dividing an area of a coil constituted by the second coil wire by an area of the second main surface.

13. A printed wiring board comprising:
a first base film having a first main surface and a second main surface as a surface opposite to the first main surface;
a first coil wire spirally formed on the first main surface; and
a second coil wire spirally formed on the second main surface, wherein
at least one of a value obtained by dividing an area of a coil constituted by the first coil wire by an area of the first main surface and a value obtained by dividing an area of a coil constituted by the second coil wire by an area of the second main surface is more than or equal to 0.40 and less than or equal to 0.90.

14. The printed wiring board according to claim 13, wherein the at least one of the value obtained by dividing the area of the coil constituted by the first coil wire by the area of the first main surface and the value obtained by dividing the area of the coil constituted by the second coil wire by the area of the second main surface is more than or equal to 0.60 and less than or equal to 0.90.

15. The printed wiring board according to claim 13, wherein the value obtained by dividing the area of the coil constituted by the first coil wire by the area of the first main surface is more than or equal to 0.95 times and less than or equal to 1.05 times the value obtained by dividing the area of the coil constituted by the second coil wire by the area of the second main surface.

16. A printed wiring board comprising:
a first base film having a first main surface and a second main surface as a surface opposite to the first main surface;
a first coil wire spirally formed on the first main surface; and
a second coil wire spirally formed on the second main surface, wherein
a value obtained by dividing a width of the first coil wire by a pitch between two adjacent portions of the first coil wire and a value obtained by dividing a width of the second coil wire by a pitch between two adjacent portions of the second coil wire are more than or equal to 0.72 and less than or equal to 0.93.
